(19) United States
(12) Patent Application Publication
(10) Pub. No.: US 2026/0213126 A1
(43) Pub. Date: Jul. 23, 2026

(54) METHOD AND DEVICE FOR CORRECTING AN IMAGING ERROR OF A PARTICLE BEAM DURING SAMPLE PROCESSING

(71) Applicant: Carl Zeiss SMT GmbH, Oberkochen (DE)

(72) Inventor: David Laemmle, Darmstadt (DE)

(21) Appl. No.: 19/565,802

(22) Filed: Mar. 13, 2026

Related U.S. Application Data
(63) Continuation of application No. PCT/EP2024/075059, filed on Sep. 9, 2024.

(30) Foreign Application Priority Data
Sep. 15, 2023 (DE) 102023208993.9

(51) Int. Cl. H01J 37/304; H01J 37/22

(52) U.S. Cl. CPC H01J 37/304; H01J 37/222

(57) ABSTRACT

The present application relates to a method and a device for correcting at least one imaging error of a particle beam during processing of a sample. The method comprises the following steps: (a) determining the at least one imaging error of the particle beam after at least one interruption of the processing of the sample; and (b) correcting the determined at least one imaging error of the particle beam if it exceeds a specified threshold value.

### CROSS-REFERENCE TO RELATED APPLICATIONS

This application is a continuation of and claims benefit under 35 U.S.C. § 120 from PCT Application No. PCT/EP2024/075059, filed on Sep. 9, 2024, which claims priority from German Patent Application DE 10 2023 208 993.9, entitled “Verfahren und Vorrichtung zum Korrigieren eines Abbildungsfehlers eines Teilchenstrahls während eines Bearbeitens einer Probe” and filed on Sep. 15, 2023. The entire contents of each of these earlier applications are incorporated herein by reference.

### TECHNICAL FIELD

The present invention relates to a method and to a device for correcting at least one imaging error of a particle beam during sample processing.

### BACKGROUND

As a consequence of the steady increase in integration density in microelectronics, photolithographic masks have to image structure elements that are becoming ever smaller into a photoresist layer of a wafer. In order to meet these requirements, the exposure wavelength is being shifted to ever shorter wavelengths. At the present time, argon fluoride (ArF) excimer lasers are principally used for exposure purposes, with these lasers emitting at a wavelength of 193 nm. Intensive work is being done in regard to light sources which emit in the extreme ultraviolet (EUV) wavelength range (10 nm to 15 nm), and corresponding EUV masks. The resolution capability of wafer exposure processes has been increased by simultaneous development of multiple variants of conventional binary photolithographic masks. Examples thereof are phase masks or phase-shifting masks and masks for multiple exposure.

Due to the ever smaller dimensions of the structure elements, lithographic masks, photomasks or simple masks cannot always be produced without defects visible or printable on a wafer. Due to the expensive production of photomasks, defective masks are repaired whenever possible. This likewise applies to microscopic samples or components, such as stamps for nanoimprint lithography.

Two important groups of defects in lithographic or photolithographic masks are dark defects. These are places where absorber and/or phase-shifting material is present, but which should be free of this material. These defects are repaired by removing the excess of material preferably with the aid of a local etching process.

Secondly, there are so-called clear defects. These are defects on the photomask which, upon optical exposure in a wafer stepper or wafer scanner, have a greater light transmissivity than an identical defect-free reference position. In mask repair processes, these defects can be corrected by depositing a material having suitable optical properties. Ideally, the optical properties of the material used for the repair should correspond to those of the absorber or phase-shifting material. The layer thickness of the repaired location can then be adapted to the dimensions of the layer of the surrounding absorber or phase-shifting material.

Usually, both types of defects are local defects, the dimensions of which are typically in the submicrometer range. These defects are often repaired by particle beam-induced local chemical processes. To repair local defects of a sample, at least one process gas or precursor gas is provided at the processing site on the sample at which a focused particle beam induces a local chemical reaction. For local removal of an excess of material from the sample, the process gas comprises at least one etching gas. In the case of the deposition of missing material, the precursor gas comprises at least one deposition gas.

In the following text, masks, stamps for nanoimprint lithography, wafers and various types of components to be repaired, such as MEMS (Micro-Electro-Mechanical System), NEMS (Nano-Electro-Mechanical System) or PICs (Photonic Integrated Circuits) are grouped together under the term sample.

In contrast to mechanical processes, such as sputter processes, chemical processes are often slow-moving processes. The sample may heat up locally while a defect is being processed. Furthermore, micromanipulators used to align the sample with the focused particle beam may experience drift over a longer period of time. In addition, the local irradiation of a sample with a charged particle beam can charge the sample locally electrostatically. In addition to sample processing, these effects can also occur when examining the sample with a focused particle beam. Therefore, the charged particle beam cannot be incident on the sample at the intended place. All the effects outlined ultimately result in a drift between an intended processing position on the sample and the incident particle beam. This will cause a deterioration of the lateral resolution of the particle beam with respect to a defective surface of the sample. This results in a deterioration of the (imaging) quality of the sample and also in a reduction in the quality of a sample repair.

This problem can be mitigated by arranging one or more marks for drift correction on the sample near a defect to be repaired. The mark(s) for drift correction can be used as a reference during sample processing to determine the extent of drift and then to correct the drift based on these data.

WO 2012/146 647 A1 describes, for example, the deposition of a reference mark on a photomask with the aid of a particle beam, a process gas and an additional gas, which may be an oxidizing gas, WO 2005/017 949 A2 describes the deposition of material on a photomask by use of an electron beam and TEOS (tetraethyl orthosilicate) or an organic or inorganic precursor gas.

In addition to a shift in the beam position due to drift processes, the beam shape or beam geometry of a focused particle beam can also be subject to change over a longer period of time. Temperature changes and the associated material changes, or, in the case of semiconducting components, additionally their function, can influence the beam shape of a particle beam. In addition, the use of a precursor gas can accelerate the change in beam geometry. For example, some of the precursor gas and/or its reaction products can penetrate into a microscope column, such as a column of an electron beam microscope, and change the beam geometry of the particle beam. In addition, hysteresis effects, which also influence the beam geometry, can occur in magnetic lenses. However, a variation in the beam shape of the particle beam during a defect processing process leads to a deterioration of the lateral process resolution and thus ultimately reduces the quality of the defect repair carried out. Moreover, an altered beam shape of the particle beam can make it difficult to determine its drift and thus adversely affect its correction. The present invention is therefore based on the aspect of providing a method and a device for correcting an imaging error of a particle beam during sample processing which allow improved sample processing.

### SUMMARY

According to an exemplary embodiment of the present invention, this aspect is achieved at least in part by the subjects of Independent Claims 1 and 17 of the present application. Exemplary embodiments are described in the dependent claims.

In one embodiment, the method for correcting at least one imaging error of a particle beam during processing of a sample comprises the steps of: (a) determining the at least one imaging error of the particle beam after at least one interruption of the processing of the sample; and (b) correcting the determined at least one imaging error of the particle beam if it exceeds a specified threshold value.

Typically, imaging errors or aberrations are understood to mean deviations from ideal particle-optical imaging that are caused by a real optical or particle-optical system. In this application, imaging errors or aberrations are not related to ideal particle-optical imaging, but rather to the best possible imaging of a real particle-optical system. An image recorded with a particle optical system having the best possible setting is referred to below as a reference image. This reference image serves as a reference variable in this application, even if the reference image exhibits a small amount of aberration. The reference variable is therefore not an ideal image representation of a reference element, but its best possible image representation with a real particle optical system.

In this application, sample processing comprises, for example, a controlled sample change. However, sample processing may also comprise a sample examination or sample analysis in which a sample is imaged and/or in which a material composition of the sample is analyzed. It is not necessary here to (substantially) change the sample or material composition.

A process for processing a sample can be interrupted, for example, from time to time or in a periodically repeated manner. During the interruption of the processing process, it is determined whether the beam shape or beam geometry of the particle beam has changed during the processing time. If this is not the case, or if the change in beam shape is less than a specified threshold value, the processing process, such as processing or repairing a defect in the sample, continues without changing the geometry of the particle beam. If, on the other hand, the change in the beam shape of the particle beam exceeds a specified threshold value, the beam shape of the particle beam is corrected in such a way that the imaging error caused by the changed beam geometry is corrected. This can prevent a deterioration of the (imaging) quality and/or degradation of the lateral process resolution of the processing process. As a result, a consistent quality of the sample processing can be ensured, i.e., a quality that is independent of the examination time and/or processing time.

Interrupting the sample processing and determining the at least one imaging error can be done in automated fashion and correcting the determined at least one imaging error can be performed manually. However, it is also possible that the interruption of the sample processing and/or the determination of the at least one imaging error is carried out by human interaction and the correction of the determined at least one imaging error is carried out in automated fashion. In a preferred embodiment, all the steps of a method according to the invention are performed completely automatically.

The magnitude of an imaging error can be determined by determining one or more parameters used in image processing. For example, broadening of structure edges can be used as a metric or error metric. When considering edge profiles, the magnitude of the first and/or second derivative can be used. Alternatively and/or additionally, variables in the Fourier space can be used to determine the at least one imaging error.

In other exemplary embodiments, the method for correcting at least one imaging error of a particle beam during sample processing may alternatively or additionally comprise the steps of: after optimizing the particle beam and recording at least one reference image of one or more structure elements near the position of the sample to be processed, processing the sample; determining at least one imaging error of the particle beam at least in part after sample processing or the processing of the sample; and correcting the determined at least one imaging error of the particle beam if it exceeds a specified threshold value.

Processing the sample may comprise using the particle beam to process the sample.

The particle beam can thus assume a dual role. It can be used to image the sample, for example, a defect in the sample and/or a reference element of the sample. In addition, the particle beam can be used to induce a local chemical reaction. As already indicated above, the performance of the second function can accelerate a change in the beam shape of the particle beam, for example, by the action of a process gas or precursor gas and/or by a temperature change resulting from the sample processing. By carrying out a method according to the invention, a change in the beam geometry of the particle beam can be corrected independently of its cause.

Alternatively, however, it is also possible that the particle beam is not actively involved in sample processing, but is configured to make sample processing visible. The sample processing can be carried out in this embodiment of a method according to the invention, for example, by a probe of a scanning probe microscope or generally by a micromanipulator. The particle beam makes it possible to track the sample processing in real time, for example, and to intervene in an automated processing process if necessary.

In addition, a first particle beam, such as an electron beam, can be used for observing or imaging a sample repair process, which is carried out by a second particle beam. In this case, the second particle beam can induce a local chemical process and/or change a sample by the sputtering effect thereof.

The particle beam can comprise a charged particle beam. The particle beam can comprise a focused particle beam. The particle beam can comprise an element from the group of: a photon beam, an electron beam, an ion beam, an atomic beam, or a molecular beam.

Both electron beams and photon beams, in particular photon beams from the deep ultraviolet (DUV) and extreme ultraviolet (EUV) wavelength ranges, can be finely focused so that the area within which an electron beam and/or a photon beam initiates a local chemical reaction of the at least one precursor gas is very small. The spatial resolution is therefore high when repairing local clear and/or dark defects.

An electron beam may have a resolution in a range from 0.4 nm to 10 nm, preferably from 0.5 nm to 8 nm, with greater preference from 0.6 nm to 6 nm, and with the greatest preference from 0.7 nm to 4 nm. Furthermore, the electron beam can have an energy in a range from 0.01 keV to 50 keV, preferably 0.02 keV to 20 keV, with greater preference 0.04 keV to 5 keV, and with the greatest preference 0.1 keV to 2 keV. Furthermore, the electron beam can have a beam current in a range from 5 pA to 5000 pA, preferably 10 pA to 1000 pA, with greater preference 15 pA to 300 pA, and with the greatest preference from 20 pA to 100 pA. These numerical values apply both to the recording of an image by scanning the electron beam over a structure and to sample processing with the electron beam and at least one precursor gas. Large beam currents, i.e., electron currents in the nanoampere range, are required in particular for material analysis, for example, for X-ray analysis, of the material of a defective sample region.

The electron beam during processing of the sample may have a dwell time in the range from 10 ns to 0.1 s, preferably 100 ns to 10 ms, with greater preference 1 μs to 1 ms, and with the greatest preference from 10 μs to 0.1 ms. In addition, the electron beam may have a repetition time (repetition time; period with which the electron beam hits the same site of the sample) in the range from 1 μs to 1 s, preferably 10 μs to 0.5 s, with greater preference 0.1 ms to 0.2 s, and with the greatest preference 1 ms to 0.1 s.

The processing of the sample may comprise providing at least one precursor gas on the sample.

Preferably, the provision of the at least one precursor gas comprises locally providing the at least one precursor gas at the processing site of the sample, for example, at the processing site of a defect of the sample. A processing process of the sample may comprise a local etching process and/or a local deposition process. Sample processing can repair a defect in the sample.

The interruption of the sample processing may at least comprise the interruption of the provision of the at least one precursor gas. Further, interrupting the processing of the sample may comprise changing at least one parameter of the particle beam before performing its second function.

However, a change in the gas supply can be dispensed with if a defect repair rate is small, i.e., the time for sample repair is large compared with the time it takes to determine and correct an imaging error of the particle beam.

Determining the at least one imaging error of the particle beam can comprise: recording at least one image of at least one reference element of the sample with the particle beam.

For recording the at least one image of the at least one reference element, it may be necessary to change one or more parameters of the imaging particle beam compared to the processing particle beam. The recording of the at least one image of the at least one reference element of the sample may comprise scanning the particle beam over the reference element. The recording of the at least one image can be done without providing a precursor gas.

The at least one reference element may comprise at least one element from the group of: at least one structure element of the sample, at least one mark for drift correction or at least one defect of the sample.

If a structure element can be used as a reference element that is already present on the sample, the process steps of producing and removing the reference element from the sample after sample processing has been completed can be omitted. This also applies if a first defect has a contour and can therefore be used as a reference element when removing a second defect from the sample.

The sample may comprise a lithographic mask and the at least one structure element may comprise at least one element from the group of: at least one absorbent and/or phase-shifting element of a pattern of the lithographic mask, at least one mark (fiducial mark) of the lithographic mask or at least one defect of the lithographic mask.

Typically, pattern elements and/or marks on a mask have contours that are suitable for using these elements as reference elements. A mask can comprise a transmissive or a reflective photomask. A photomask may comprise any mask type.

A method according to the invention may furthermore comprise the following step: depositing a sacrificial layer on the sample and/or a protective layer around a processing site of the sample with a particle beam and at least one precursor gas in the form of a deposition gas.

The deposition of a protective layer on the sample around or at least partially around a defect to be processed or corrected protects the region of the sample surrounding the defect from negative effects of the sample processing. If the defect is corrected by depositing material, the protective layer prevents material from being accidentally deposited outside the defect. The same applies to a defect that is processed by a local etching process. In this case, a protective layer surrounding the defect prevents etching and thus an unintended change in the sample outside the defect.

Deposition of a sacrificial layer near a processing site provides an additional degree of freedom when depositing a mark for drift correction. For example, the material composition of the mark can be selected independently of the material of the sample. In addition, the sacrificial layer protects the sample from potential removal effects due to scanning the particle beam over the sample for recording an image of the reference element for determining the at least one imaging error and/or for determining a drift.

Producing the sacrificial layer and/or the protective layer may comprise performing a particle-beam-induced local chemical reaction.

A sacrificial layer and/or a protective layer may have a material composition that allows easy removal of this/these layer(s) after completion of the sample processing.

The height of the sacrificial layer and/or of the protective layer may lie in a range from 5 nm to 2000 nm, preferably from 10 nm to 1000 nm, with greater preference from 20 nm to 500 nm, and with the greatest preference from 50 nm to 300 nm. The lateral dimensions of the sacrificial layer may exceed the lateral dimensions of a mark for drift correction by a factor of 1.2, preferably by a factor of 1.5, with greater preference by a factor of 2, and with the greatest preference by a factor of 5. The protective layer may have in the smaller lateral dimension dimensions in the range from 5 nm to 1000 nm, preferably 10 nm to 500 nm, with greater preference from 20 to 300 nm, and with the greatest preference from 30 nm to 200 nm.

The deposition of the sacrificial layer, the protective layer and/or of material on a defect of missing material can be performed at a rate of 0.01 nm/s to 1 nm/s, preferably 0.02 nm/s to 0.5 nm/s, with greater preference 0.04 nm/s to 0.3 nm/s, and with the greatest preference 0.05 nm/s to 0.15 nm/s. The etching of the sacrificial layer, the protective layer and/or excess defect material can be performed at a rate of 0.01 nm/s to 1 nm/s, preferably 0.02 nm/s to 0.5 nm/s, with greater preference 0.04 nm/s to 0.3 nm/s, and with the greatest preference 0.05 nm/s to 0.15 nm/s.

For depositing the sacrificial layer and/or the protective layer, the particle beam that processes the sample can be used. However, it is also possible to use a different particle beam for this purpose. The deposition of the sacrificial layer and the protective layer can be performed with a deposition gas or with a deposition gas combination. In turn, however, it is also possible to use a specific deposition gas or a specific deposition gas combination to deposit each of the layers.

The at least one deposition gas for depositing the sacrificial layer and/or the protective layer may contain carbon. Layers that contain a large amount of carbon can be removed from a sample using a wet chemical process. Such cleaning processes are typically used to clean the processed sample after sample processing has been completed.

The at least one reference element may have a material contrast with respect to the sample and/or to the sacrificial layer. The at least one mark for drift correction may have a material composition that is different from the material composition of the sample and/or the sacrificial layer.

A mark for drift correction may comprise as the main components molybdenum (Mo), carbon (C) and oxygen (O). If an electron beam is used as a particle beam, marks with this material composition provide, in addition to a topography contrast, a material contrast, typically with respect to both a sample and a sacrificial layer lying below the mark. For example, in the absence of an oxidizing agent during the deposition of a mark for drift correction, the latter may have a material composition: Mo_{10%-15%}C_{70%-75%}O_{15%}. When using an effective oxidizing agent, a deposited mark for drift correction may substantially comprise MoO₃. This shows that a mark for drift correction typically always contains at least as much carbon or oxygen as molybdenum.

The term “substantially” here means—as in other places in this description—an indication of a measured variable within the usual error limits, wherein measuring technology according to the state of the art is used for measuring the variable.

Marks for drift correction can have many different shapes. Small marks with sharply defined contours, such as cylindrical or conical structures, are preferred. Marks with easy-to-produce topographic figures, such as cuboids or cubes, are also beneficial. Preferably, a plurality of marks for drift correction are arranged around a sample location to be repaired. Two to five marks have also proved to be favorable from an economic point of view.

The height of a mark for drift correction may lie in a range from 1 nm to 1000 nm, preferably 5 nm to 500 nm, with greater preference 20 nm to 300 nm, and with the greatest preference 40 nm to 100 nm. The lateral dimensions of a mark for drift correction are preferably smaller than the structure elements of a sample. This means that for a photomask as a sample, the lateral dimensions of a mark should be smaller than the smallest dimension of the pattern elements of the mask. The lateral dimensions of a mark for drift correction may lie in a range from 1 nm to 500 nm, preferably 2 nm to 250 nm, with greater preference 5 nm to 150 nm, and with the greatest preference 10 nm to 75 nm.

A reference element and/or a mark for drift correction always has in the image of the particle beam a topography contrast with respect to the sample or a sacrificial layer on which the mark is placed. If the reference element or the mark for drift correction has a material composition different from the sample or sacrificial layer, the image recorded by the particle beam additionally contains a material contrast. This makes it easier to determine an imaging error of the particle beam.

The at least one mark for drift correction may have a material contrast with respect to the sample and/or to the sacrificial layer,

The at least one reference element may be arranged within a scanning region of the particle beam. The particle-beam-induced local chemical process can produce the at least one mark for drift correction within a scanning range of the particle beam. A maximum scanning range is understood to mean below an area with dimensions in the micrometer range, approximately 20 μm·20 μm or 50 μm·50 μm.

When arranging or placing a reference element, two boundary conditions must be observed. If the distance between the reference element and the processing site is too small, the reference element may be negatively affected by the sample processing, which can reduce its function as a reference for correcting imaging errors of the particle beam and/or for drift correction. On the other hand, if the distance of the mark from the processing site is too large, i.e., outside a scanning range of the particle beam, position-dependent aberrations, such as coma and/or image field curvature, cannot be correctly detected and corrected, since the sample must be displaced relative to the particle beam in order to scan the mark. The displacement of the sample relative to the particle beam has a detrimental effect on the precision with which at least the drift of the particle beam can be determined. In addition, large distances between the reference element(s) and the defective sample location can negatively affect positioning accuracy. Advantageous distances range from 0.2 μm to 100 μm.

Producing the at least one mark for drift correction can comprise at least one element from the group of: depositing the at least one mark for drift correction on the sample, depositing the at least one mark for drift correction on the sacrificial layer, etching the at least one mark for drift correction into the sample, and etching the at least one mark for drift correction into the sacrificial layer. A mark for drift correction etched into a sacrificial layer and/or the sample may have similar dimensions to a mark deposited on the sample and/or the sacrificial layer.

If a mark is produced on an absorbent pattern element of a photomask whose lateral dimensions are significantly smaller than the smaller lateral dimension of an absorbent pattern element and this mark can be deposited centrally on the pattern element, the mark may remain on thereon after sample processing has been completed, since it does not substantially interfere with the operation of the photomask. In all other cases, it is advantageous to apply the at least one mark for drift correction on a sacrificial layer, which is designed in such a way that it can be removed from the sample, for example, a photomask, in a simple manner, for example, by a wet chemical cleaning process. This allows the at least one mark for drift correction to be removed from the sample together with the sacrificial layer. This can be done in a particularly simple way if the mark is produced as a structure etched into the sacrificial layer.

A method according to the invention may furthermore comprise the following step: performing a local particle-beam-induced local chemical reaction to produce the at least one mark for drift correction. The particle beam whose imaging errors are corrected can be used for producing the at least one mark for drift correction. However, it is also possible to use a particle beam which has a different type of particle for producing the at least one mark for drift correction. For example, the imaging error(s) of an electron beam which is used for sample processing can be corrected, and the sacrificial layer, the protective layer and/or the at least one mark for drift correction can be deposited by use of a photon beam or an ion beam.

The sample may comprise a lithographic mask and the at least one structure element may comprise at least one element from the group of: a pattern element of the lithographic mask or a fiducial mark of the lithographie mask. Furthermore, the sample may comprise an embossing stamp of nanoimprint lithography, and the at least one reference element may comprise a structure element of the embossing stamp.

Determining the at least one imaging error may comprise: analyzing at least one recorded image with respect to at least one reference.

The at least one reference may comprise at least one element from the group of: at least one reference image of the at least one reference element, stored data which have been determined from the at least one reference image of the at least one reference element, at least one reference image recorded by the particle beam, stored data which have been determined from the at least one reference image recorded by the particle beam, a database with at least two images of the at least one reference element which were recorded with a particle beam having at least one defined imaging error, or a database with stored data determined from the at least two images of the at least one reference element which were recorded with a particle beam.

A reference image of a reference element is an image that a particle beam produces from the reference element, wherein the imaging error(s) is/are minimal. The at least one reference image of the at least one reference element may comprise a reference image that looks as if it had been recorded with the particle beam. This means that a reference image of the at least one reference element can be recorded by another, such as a second, particle beam, and transformed into a reference image that looks as if the particle beam had recorded the reference image.

A method according to the invention may further comprise systematically changing at least one parameter of the particle beam before recording at least one of the at least two images of the at least one reference element for producing the at least one defined imaging error.

Images of a reference element can be stored in a database, with one or more parameters of the particle beam varying systematically during the recording thereof. This changes the beam shape of the particle beam in a defined manner, so that the particle beam produces images of the reference element with defined imaging errors. The database can contain images that comprise individual imaging errors of different severity. Furthermore, the database may comprise images during the recording of which the particle beam has a combination of two or more aberrations of different severity.

For these images, it is known which parameter change(s) in relation to the best possible setting produced the corresponding image. By determining the image stored in the database that comes closest to the measured image of the reference element, the parameter change(s) that eliminate the imaging errors can be determined so that the particle beam with the changed parameter settings produces a reference image of the reference element when an image of the reference element is recorded again.

A database can be set up prior to sample processing. During the processing process, all that is required then is an image comparison to determine the parameters that correct the imaging error(s) of the particle beam. This type of imaging error correction therefore has little influence on the progress of the processing process.

Correcting the determined at least one imaging error may comprise the use of at least one element from the group of: an auto-correction function and a trained model of machine learning. The auto-correction function may comprise at least one algorithm which is configured to determine the imaging error(s) of the particle beam by comparing the recorded image of the at least one reference element with a reference image of the at least one reference element.

Executing the algorithm underlying the auto-correction function is computationally intensive and therefore takes some time. The algorithm must be executed during the sample processing. In particular, it can only be decided after the algorithm has been executed whether the particle beam actually needs to be corrected. The time of sample processing can therefore be extended by this way of correcting imaging errors.

The trained model of machine learning can be provided with at least one element from the following group as input data: a material composition of the sample, a sample processing type, a particle beam type, at least one parameter of the particle beam, at least one component of the at least one precursor gas used, or at least one environmental parameter of the sample processing. In addition, the model of machine learning can be trained using the data from identical or similar processing or repair processes.

The environmental parameters may comprise at least one element from the group of: a temperature at the sample processing site, a pressure at the sample processing site, or a humidity at the sample processing site.

The trained model of machine learning can determine a time interval of a sample processing loop. A time interval of the loop may comprise the time interval between a start of the sample processing and a first interruption of the sample processing, or in general the n-th time interval may comprise the time interval between the (n-1)-th and the n-th interruption of the sample processing. The trained model of machine learning can determine the n-th time interval from the n-1 input data of the previous sample processing.

Training a model of machine learning can comprise: training a model of machine learning with a number of images with imaging errors with associated input data and a number of reference images with associated input data.

A model of machine learning produces knowledge from experience. A model of machine learning learns from examples that are provided to the model in the form of training or learning data in a learning or training phase. Using this, internal variables of the model, for example, parameters of parametric mapping, can be populated by suitable values in order to be able to describe relationships in the training data. As a result, the model of machine learning does not usually simply memorize the training data during the training phase, but rather identifies patterns and/or regularities in the training data.

The quality of the learned relationships is typically assessed on the basis of validation data in order to assess the generalizability of the trained model to new data, i.e., data that is unknown during the training. A trained model of machine learning can be applied for correcting imaging errors of a particle beam to predict the potential effects of changes in the beam shape of the particle beam in an image of the reference element unknown to the model of machine learning when providing the associated input data. A successfully trained or learned model of machine learning, i.e., a trained model of machine learning with good generalizability, is therefore able after the training phase to assess unknown images of the reference element when providing the associated input data.

A model of machine learning can comprise at least one element from the group of: parametric mapping, an artificial neural network (ANN), a deep neural network (DNN), a time-delayed neural network, a convolutional neural network (CNN), a recurrent neural network (RNN), a long short-term memory (LSTM) network, and a generative model.

The correction of the particular imaging error may comprise changing at least one parameter of the particle beam, with the result that the particle beam with the at least one changed parameter generates substantially one reference image when recording an image of the at least one reference element.

The at least one imaging error of the particle beam can be determined by recording and analyzing one or more images, such as the reference mark(s). In order to minimize the disruption to the progress of the processing process by the determination of the imaging error, the recording time for the one or more images should be as short as possible. In addition, the time to analyze the image(s) to determine the imaging error should be kept as short as possible. Auto-correction processes that require a small number of steps that need to be performed are therefore preferred.

A method according to the invention may furthermore comprise the following step: continuing the sample processing without correcting the particle beam if its imaging error is smaller than a specified threshold value, or correcting the at least one imaging error of the particle beam and continuing the sample processing with the particle beam with at least one changed parameter if its imaging error is greater than or equal to a specified threshold value. For example, a threshold value can be defined as a percentage of a deterioration compared to an image representation recorded with the best possible settings of a particle beam. The deterioration of the imaging can be related to the growth of an imaging error, such as the dominant imaging error, or to two or more types of different imaging errors, such as defocusing, astigmatism, coma, etc. For example, a threshold value can be defined as a doubling of the imaging error of an image representation relative to a reference image representation, i.e., at the best possible settings of the parameters of the particle beam.

The at least one imaging error of the particle beam may comprise at least one element from the group of: a change in focus, a change in astigmatism or a change in coma.

An imaging error may exhibit deviations in at least two directions from the best possible setting. For example, a change in focus can mean overfocusing or underfocusing. It is often difficult to detect which direction of the deviation is (are) the cause of the detected aberration(s). However, this is necessary in order to be able to correct the imaging error(s). In this context, the images stored in the database may be helpful in determining the parameter change(s) of the particle beam that correct the detected aberration(s) of the particle beam.

The at least one imaging error can comprise a drift of the particle beam relative to the sample and an element from the group of: a change in focus, a change in astigmatism or a change in coma.

Recording a single image of at least one reference element allows both the determination of the severity of the aberrations of the particle beam and its drift relative to the sample. Thus, carrying out a method according to the invention can significantly improve the quality of sample processing.

The at least one precursor gas may comprise at least one element from the group of: at least one etching gas, at least one deposition gas or at least one additive gas.

The at least one precursor gas may comprise a first deposition gas for depositing the at least one mark for drift correction, the at least one sacrificial layer and/or the at least one protective layer. The at least one first deposition gas may comprise at least one element from the group of: metal alkyls, transition element alkyls, main group alkyls, metal carbonyls, transition element carbonyls, main group carbonyls, metal alkoxides, transition element alkoxides, main group alkoxides, metal complexes, transition element complexes, main group complexes, or organic compounds.

The at least one precursor gas may comprise a second deposition gas for producing the at least one mark for drift correction. The at least one second deposition gas may comprise at least one element from the group of: tetraethyl orthosilicate (Si(OC₂H₅)₄), metal carbonyls, transition element carbonyls, or main group carbonyls.

The at least one metal carbonyl may comprise at least one element from the group of: chromium hexacarbonyl (Cr(CO)₆), molybdenum hexacarbonyl (Mo(CO)₆), tungsten hexacarbonyl (W(CO)₆), dicobalt octacarbonyl (Co₂(CO₈)), triruthenium dodecacarbonyl (Ru₃(CO)₁₂), and iron pentacarbonyl (Fe(CO)₅). The at least one main group element alkoxide may comprise at least one element from the group of: tetraethyl orthosilicate (Si(OC₂H₅)₄, TEOS) tetramethyl orthosilicate (Si(OCH₃)₄, TMOS) or titanium tetraisopropoxide (Ti(OCH(CH₃)₂)₄).

The at least one precursor gas may comprise at least one additive gas from the group of: an oxidizing agent, a halide, or a reducing agent.

The oxidizing agent may comprise at least one element from the group of: oxygen (O₂), ozone (O₃), water vapor (H₂O), hydrogen peroxide (H₂O₂), nitrous oxide (N₂O), nitrogen oxide (NO), nitrogen dioxide (NO₂), or nitric acid (HNO₃). The halide may comprise at least one element from the group of: chlorine (Cl₂), hydrochloric acid (HCl), xenon difluoride, hydrofluoric acid (HF), iodine (I₂), hydrogen iodide (HI), bromine (Br₂), hydrogen bromide (HBr), nitrosyl chloride (NOCl), phosphorus trichloride (PCI₃), phosphorus pentachloride (PCL₅), or phosphorus trifluoride (PF₃). The reducing agent may comprise at least one element from the group of: hydrogen (H₂), a mania (NH₃), or methane (CH₄).

The first deposition gas may comprise molybdenum hexacarbonyl (Mo(CO)₆), the at least one additive gas may comprise nitrogen dioxide (NO₂), and the second deposition gas may comprise tetraethyl orthosilicate (Si(OC₂H₅)₄) or chromium hexacarbonyl (Cr(CO)₆).

The at least one reference element may comprise at least one mark for drift correction, and a method according to the invention may further comprise the step of: removing the at least one mark for drift correction from the sample.

The removal of the at least one sacrificial layer and the at least one mark for drift correction can be effected in one common process step. The removal of the at least one sacrificial layer and/or the at least one mark for drift correction can be effected in a wet chemical cleaning process of the sample.

A computer program may comprise instructions that cause a computer system to perform the method steps of the above-described aspects of a method according to the invention when the computer program is executed by the computer system.

A computer-implemented method for correcting at least one imaging error during sample processing comprises: (a) receiving at least one image of at least one reference element; (b) comparing the at least one received image of the at least one reference element with at least one or more stored images of the at least one reference element for automatically determining the at least one imaging error; and (c) automatically changing at least one parameter of the particle beam so that the particle beam having the at least one changed parameter has an imaging error which is smaller than a specified threshold value.

A method according to the invention can be implemented in such a way that it can proceed without human interaction. Thus, a method according to the invention can be objectified, i.e., released from subjective human assessment. In addition, the method can be integrated into a sample processing process in such a way that the time for sample processing is only minimally extended.

In one embodiment, the device for correcting at least one imaging error of a particle beam during processing of a sample comprises: (a) means for determining the at least one imaging error of the particle beam after at least one interruption of the processing of the sample; and (b) means for correcting the determined at least one imaging error of the particle beam if it exceeds a specified threshold value.

The device may further comprise at least one element from the group of: means for providing at least one precursor gas on the sample, means for guiding and controlling a gas flow rate of the at least one precursor gas, means for producing, focusing and scanning the particle beam, means for adjusting a focus, means for correcting an astigmatism and a coma error of the particle beam, means for adjusting an objective lens used for focusing the particle beam, means for displacing the sample in the beam direction of the particle beam, means for adjusting a stigmator, means for positioning the particle beam relative to a multi-aperture stop, means for positioning the multi-aperture stop relative to the particle beam, or means for positioning the particle beam inside and/or outside a particle beam column.

A device according to the invention may further comprise: a stigmator for changing an astigmatism of the particle beam.

The stigmator may comprise at least one electrical and/or magnetic multipole element, which generates an electric and/or magnetic field which is directed substantially perpendicular to the beam direction of the particle beam.

The electric and/or magnetic multipole element of the stigmator can generate a quadrupole field.

The electric and/or magnetic multipole element may comprise a quadrupole, hexapole, octupole and/or dodecapole element.

Coma errors can be corrected by positioning the particle beam in the particle beam column. A drift of a position of incidence of the particle beam on the sample can be corrected by positioning the particle beam outside the particle beam column.

A device according to the invention may also have a multi-aperture stop for generating a specified particle current.

The multi-aperture stop may comprise two to ten, preferably three to nine, with greater preference four to eight, and with the greatest preference five to seven apertures. The opening widths of the different apertures of the multi-aperture stop may differ. The particle beam can be shaped by selecting the stop with the corresponding opening width through which the particle beam passes.

The opening width of at least one of the stops of the multi-aperture stop may be adjustable in a range from 0.1 μm to 1000 μm, preferably from 0.2 μm to 500 μm, with greater preference from 0.5 μm to 200 μm, and with the greatest preference from 1 μm to 100 μm.

The multi-aperture stop may be positioned in the microscope column upstream of the objective lens in the beam direction. The multi-aperture stop can be used to adjust the size of the particle beam stream.

A device according to the invention may further have an extractor stop and/or an anode stop at the output of the particle gun.

The device may be set up to perform the method steps according to any of the above aspects.

The device may further comprise a computer system with a computer program described above.

In addition, the device may contain one or more algorithms that is/are configured to interrupt the sample processing, determine an imaging error, and correct the determined imaging error. One or more algorithms can be implemented in hardware, software, firmware or a combination thereof.

### DESCRIPTION OF DRAWINGS

The detailed description that follows describes currently preferred exemplary embodiments of the invention with reference to the drawings, wherein:

FIG. 1 schematically illustrates in the upper partial diagram a block diagram of some important components of a device which can be used to correct one or more imaging errors of a particle beam during sample processing and which can be used in addition to determine and correct a drift of the particle beam, and the lower partial diagram illustrates a schematic section through a cleaning device for a sample;

FIG. 2 shows a schematic view of a detail of a photomask, as an example of a sample, having a defect of an excess of material on the mask substrate;

FIG. 3 shows the detail from FIG. 2 after an interruption of the defect processing and a re-scanning of the mark for drift correction to determine an imaging error and/or a drift of the particle beam;

FIG. 4 shows the detail from FIG. 3 after drift correction of the focused particle beam before continuing the sample processing;

FIG. 5 shows a top view of an exemplary reference element in the form of three sharply depicted point-like structures;

FIG. 6 shows the reference element of FIG. 5, which was recorded with an imaging error of the focused particle beam in the form of defocusing;

FIG. 7 shows the reference element of FIG. 5, which was recorded with a focused particle beam having an imaging error in the form of an astigmatism;

FIG. 8 schematically illustrates an exemplary method for correcting imaging errors of a focused particle beam and a drift of the focused particle beam during sample processing; and

FIG. 9 shows a flowchart of essential steps of the method for correcting at least one imaging error of the particle beam during sample processing.

### DETAILED DESCRIPTION

In the following text, currently preferred embodiments of a device according to the invention for correcting imaging errors and/or a drift of a particle beam during sample processing will be explained in more detail using the example of a modified scanning electron microscope. However, a device according to the invention is not limited to the example described below. As will be recognized without difficulty by a person skilled in the art, instead of the scanning electron microscope discussed it is possible to employ any scanning particle microscope which uses, for example, a focused ion beam and/or a focused photon beam as energy source. Furthermore, a method according to the invention is not limited to the use of the photomask which will be discussed below as an example, as a sample. Rather, it can be used to repair any lithographic masks. Moreover, the application of a method according to the invention is not limited to the application on photomasks. Rather, it can be used for repairing stamps or templates for nanoimprint lithography or generally for correcting microstructured elements, such as wafers, MEMS, NEMS or PICs. Moreover it is possible to use a device according to the invention for analyzing the material composition of a sample in addition to or independently of sample processing. For example, some analysis methods, such as energy dispersive X-ray spectroscopy (EDX), require the provision of larger high-resolution electron quantities or electron doses over a longer period of time in order to obtain spatially resolved information about the material composition of a sample.

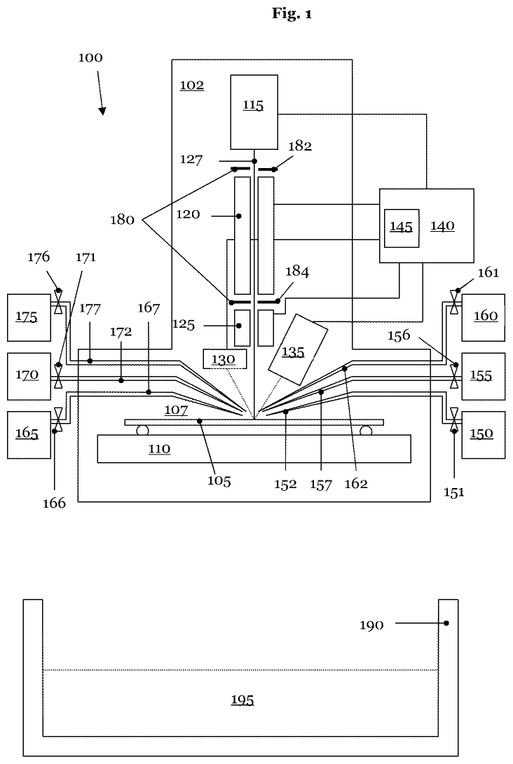

FIG. 1 schematically illustrates essential components of a device 100 which can be used for correcting imaging errors of a particle beam and/or for correcting a drift of the particle beam during a processing process of a sample 105. The sample 105 may be any microstructured component or structural part. For example, the sample 105 may comprise a transmissive or a reflective photomask and/or a template for nanoimprint lithography. Furthermore, the device 100 can be used for processing, for example, an integrated circuit, a wafer, a micro-electro-mechanical system (MEMS), a nano-electro-mechanical system and/or a photonic integrated circuit (PIC) exhibiting defects, for example, missing material and/or an excess of material. In the examples which will be explained below, the sample 105 is a lithographic mask.

The exemplary device 100 in FIG. 1 is a modified scanning electron microscope (SEM). An electron gun 115 generates an electron beam 127, which is directed as a focused electron beam 127 by the elements 120 and 125 onto the lithographic mask arranged on a sample stage 110.

The sample stage 110 has micromanipulators (not shown in FIG. 1) with the aid of which the defective location of the photomask 105 can be brought beneath the point of incidence of the electron beam 127 on the photomask 105. In addition, the sample stage 110 can be displaced in height, i.e., in the beam direction of the electron beam 127, such that the focus of the electron beam 127 comes to rest on the surface of the photomask (likewise not illustrated in FIG. 1). The electron beam 127 can be focused by a height adjustment of the sample stage 110. However, this also means that a slip or drift of the height adjustment of the sample stage 110 results in defocusing of the electron beam 127. A variation in the height of the sample 105 can occur in both directions, i.e., upwards or downwards, which can lead to overfocusing or underfocusing. In addition to a height adjustment of the sample stage 110, the focusing of the electron beam 127 can also be reversed or adjusted by changing the focusing effect of the objective lens of the device 100.

Furthermore, the sample stage 110 may include a device for adjusting and controlling the temperature, which allows the mask to be brought to a specified temperature and be kept at this temperature (not specified in FIG. 1). In addition, the temperature and further parameters that characterize the environment of the device 100 and/or the interior of the particle beam column including its electronic components, such as the air pressure and/or the humidity, can be measured and regulated. For this purpose, a liquid cooling system and/or a chiller can be used.

The device 100 typically comprises a plurality of stops 182, 184, or a stop system 180. Behind the electron gun 115, an extractor stop and an anode stop are mounted in the column of the device 100, which are illustrated in FIG. 1 by the reference numeral 182. In the exemplary device 100 shown in FIG. 1, the stop system 180 also comprises a stop 184 which has a plurality of openings of differing diameters. Typically, the stop 184 or the multi-aperture stop 184 is fixedly installed in the microscope column. First deflection systems guide the electron beam 127 through the corresponding opening of the multi-aperture stop 184, depending on the operating point to be set (for example, the sample current, if necessary the resolution and/or the depth of field). One or more second deflection systems, which are arranged below the multi-aperture stop 184, deflect the electron beam 127 leaving the corresponding opening of the multi-aperture stop 184 in such a way that it passes through the center of the objective lens 125. The first and the second deflection system or the first and the second deflection systems may comprise, for example, electrical and/or magnetic deflection systems. The deflection systems are suppressed in FIG. 1. The coma error of the electron beam 127 can be minimized by the electron beam 127 passing through the center of the objective lens 125.

However, in an alternative embodiment, it is also possible that the multi-aperture stop 184 is designed to be movable perpendicular to the beam direction and to guide the electron beam 127 or the particle beam 127 through the opening of the multi-aperture stop 184 of the corresponding width or diameter by displacing the multi-aperture stop 184 in a plane perpendicular to the beam direction of the electron beam 127. The at least one first and the at least one second deflection system and/or the lateral displacement of the multi-aperture stop can be adjusted by the control unit 145 of the device 100. The size of the particle stream can be adjusted via the selected opening width of the multi-aperture stop 184. By guiding the electron beam 127 through the center of the objective lens 125 independently of its beam strength, its coma error can be minimized.

A distance of the stops 182 (extractor stop and/or anode stop) and the multi-aperture stop 184 of the stop system 180 in the beam direction of the electron beam 127 can be 1 cm, preferably 2 cm, with greater preference 5 cm, and with the greatest preference 10 cm. The number of apertures can range from two to 20. Five to seven apertures of the multi-aperture stop 184 are currently preferred. The opening diameters of the multi-aperture stop 184 preferably have numerical values in the range from 1 μm to 50 μm. It is advantageous to guide the particle beam 127 precisely positioned through the opening of the multi-aperture stop 184, so that it can pass through the optical center of the downstream objective lens 125. It is thus possible to substantially achieve coma-freedom of the particle beam 127 incident on a sample 105.

Furthermore, the device 100 has a stigmator, which is not shown in FIG. 1. The stigmator comprises an octupole element that generates an electric field in the form of a quadrupole. The stigmator is used to correct aberrations of the electron beam 127 in the form of astigmatism.

The device 100 of FIG. 1 uses an electron beam 127 as the energy source 127 for initiating a local chemical reaction of a precursor gas or a mixture of two or more precursor gases. An electron beam 127 can be focused on a small focal spot with a diameter of <10 nm, preferably <5 nm. In addition, electrons incident on the surface of the photomask cause hardly any damage to the mask 105, even if their kinetic energy varies over a large energy range. However, the device 100 and the methods presented herein are not limited to the use of an electron beam 127. Rather, any particle beam which is able to locally effect a chemical reaction of a precursor gas at the point of incidence of the particle beam on the surface of a sample 105, such as the photomask 105 and which can generate the image data from a sample surface can be used. Examples of alternative particle beams are an ion beam, an atomic beam, a molecular beam and/or a photon beam. Furthermore, it is possible to use two or more particle beams in parallel. In particular, it is possible to simultaneously use an electron beam 127 and a photon beam or an ion beam as the energy source 127 (not shown in FIG. 1).

The electron beam 127 can be used for recording an image of the photomask, in particular a defective location of the photomask. A detector 130 for detecting backscattered electrons (BSE) and/or secondary electrons (SE) provides a signal proportional to the surface contour and/or the composition of the photomask.

By scanning the electron beam 127 over the photomask with the aid of a control unit 145, a computer system 140 of the device 100 can generate an image of the photomask. In particular, at the best possible parameter settings of the electron beam 127 it is possible by scanning the electron beam 127 over one or more reference elements present on the sample 105 to record a reference image of the reference element(s) before the start of a processing process of the sample 105, i.e., the photomask in FIG. 1. The best possible setting of the parameters of the electron beam 127 is a setting in which the focused electron beam 127 has the smallest imaging error or the least amount of aberrations that the device 100 allows.

In addition to the recording of a reference image of one or more reference elements present on the sample 105, a database containing images of one or more reference elements with a defined proportion of aberrations can be produced prior to the start of sample processing by a systematic parameter mismatch. It is thus possible to reverse the aberrations of the images in this database by reversing the defined parameter mismatch, as a result of which the images in the database are converted back into the corresponding reference images. Consequently, the produced database can be used to correct aberrations of a particle beam that the latter “acquires” during sample processing. For this purpose, the computer system 140 carries out a quantification of the image properties, which are used for determining the imaging error(s) of the particle beam 127.

The control unit 145 may be part of the computer system 140 as illustrated in FIG. 1, or may be designed as a separate unit (not shown in FIG. 1). The computer system 140 may include algorithms which are realized in hardware, software, firmware or a combination thereof and which allow an image of a reference element and/or a defect of the sample 105 to be extracted from the measurement data of the detector 130. A screen of the computer system 140 (not shown in FIG. 1) can represent the calculated image. Furthermore, the computer system 140 can store the measurement data of the detector 130 and/or the calculated image. Furthermore, the control unit 145 of the computer system 140 can control the electron gun 115 and the beam path through the beam-imaging and beam-shaping elements 120 and 125 of the device 100. Control signals of the control unit 145 can furthermore control the movement of the sample stage 110 by use of micromanipulators (not indicated in FIG. 1).

Furthermore, the computer system 140 and/or the control unit 145 may have one or more algorithms which are stored in a non-volatile memory (not shown in FIG. 1) of the computer system 140 and/or the control unit 145. The algorithms can determine the aberrations of the particle beam 127 by comparing a recorded image of one or more reference elements with a reference image of the one or more reference elements. The algorithm(s) can also determine the parameter change(s) that minimize the aberrations of the particle beam 127. Thus, the algorithm or algorithms can be considered to be an auto-correction function, which eliminates as far as possible the imaging errors of the electron beam 127.

The electron beam 127 that is incident on the photomask can electrostatically charge the photomask. This can cause the electron beam 127 to be deflected and reduce the spatial resolution during the recording of an image of a reference element or defect and during the repair of the defect. To reduce electrostatic charging of the photomask, an ion gun 135 can be used to irradiate the surface of the photomask with ions of low kinetic energy. For example, argon ions with a kinetic energy of some 100 eV can be used to neutralize the photomask 105. Alternatively and/or additionally, an electrically conductive grid mounted on the output of the column can be used for charge compensation.

In order to process the sample 105 or the photomask arranged on the sample stage 110, i.e., to repair its defects, the device 100 has at least three storage containers for three different processing gases, process gases or precursor gases. The first storage container 150 stores a first precursor gas in the form of a deposition gas. In the first storage container 150, for example, a main group element alkoxide, such as TEOS, can be stored, which can be used to repair a defect of the photomask, such as a mask substrate missing material.

The second storage container 155 stores an etching gas, such as xenon difluoride (XeF₂). Other examples of etching gases that can be stored in the second storage container are: a halogen, such as chlorine (Cl₂), fluorine (F₂), bromine (Br₂) or iodine (I₂), oxygen (O₂), ozone (O₃) and nitrosyl chloride (NOCI).

The third storage container 160 stores an oxidizing agent. An oxidizing agent can comprise, for example, an element from the group of: oxygen (O₂), ozone (O₃), water vapor (H₂O), hydrogen peroxide (H₂O₂), dinitrogen monoxide (N₂O), nitrogen monoxide (NO), nitrogen dioxide (NO₂), nitric acid (HNO₃) and other oxygen-containing compounds.

The fourth, optional storage container 165 can, for example, store a reducing agent such as hydrogen (H₂), ammonia (NH₃) and methane (CH₄).

The fifth, also optional storage container 170 can store a carbon-containing precursor gas. The precursor gas stored in the fifth storage container 170 may be, for example, a metal carbonyl, such as chromium hexacarbonyl (Cr(CO)₆) or molybdenum hexacarbonyl (Mo(CO)₆). A metal carbonyl can be used to deposit a protective layer around a defect to be processed. In addition, a metal carbonyl may be used for depositing one or more marks for drift correction used as reference elements during sample processing. In addition, a metal carbonyl, preferably Mo(CO)_{6,}, can be used as a deposition gas for depositing a sacrificial layer and/or a protective layer.

Finally, the sixth, optional storage container 175 may contain a second etching gas. The latter can be used to repair defects of an excess of material (dark defects) of the photomask. In addition, the etching gas stored in the sixth container 175 can be used to remove the reference elements in the form of marks for drift correction, a sacrificial layer and/or a protective layer from the photomask again.

Each storage container 150, 155, 160, 165, 170, 175 has its own control valve 151, 156, 161, 166, 171, 176 to control the amount of the corresponding gas provided per unit time, i.e., the gas flow at the point of incidence of the electron beam 127 on the sample 105. The control valves 151, 156, 161, 166, 171 and 176 are controlled and monitored by the control unit 145 of the computer system 140. The partial pressure ratios of the gases provided at the processing site can thus be set in a wide range.

Furthermore, in the exemplary device 100, each storage container 150, 155, 160, 165, 170, 175 has its own gas supply system 152, 157, 162, 167, 172, 177, which ends with a nozzle near the point of incidence of the electron beam 127 on the photomask 105. In an alternative embodiment (not represented in FIG. 1), a gas feed line system is used to bring a plurality or all of the processing gases in a common stream onto the surface of the sample 105.

In the example illustrated in FIG. 1, the valves 151, 156, 161, 166, 171, 176 are arranged in the vicinity of the corresponding containers 150, 155, 160, 165, 170, 175. In an alternative arrangement, the control valves 151, 156, 161, 166, 171, 176 can be incorporated in the vicinity of the corresponding nozzles (not shown in FIG. 1). Unlike the illustration shown in FIG. 1 and without preference at the present time, it is also possible to provide one or more of the gases stored in the containers 150, 155, 160, 165, 170, 175 non-directionally in the lower part of the vacuum chamber 102 of the device 100. In this case, it is necessary to install in the device 100 a screen (not shown in FIG. 1) between the lower reaction chamber 107 and the upper part 102 of the device 100 which provides the electron beam 127 to prevent an insufficient vacuum in the upper part of the device 100.

Each of the storage containers 150, 155, 160, 165, 170 and 175 may have its own temperature setting element and control element that enables both cooling and heating of the corresponding storage containers. These allow the storage and provision of the precursor gases at the respective optimum temperature (not shown in FIG. 1). This also allows the control valves 151, 156, 161, 166, 171 and 176 to be used as digital elements and the gas flow or flow rate to be controlled via a heater of the storage containers 150, 170, 160, 165, 155, 175, i.e., via the vapor pressure of the precursor gases. Moreover, each supply system 152, 157, 162, 167, 172 and 177 may comprise its own temperature setting element and temperature control element to provide all process gases or precursor gases at their optimum processing temperature at the point of incidence of the electron beam 127 on the photomask 105 (also not indicated in FIG. 1). The control unit 145 of the computer system 140 can control the temperature setting elements and the temperature control elements both of the storage containers 150, 155, 160, 165, 170, 175 and of the gas supply systems 152, 157, 162, 167, 172, 177.

The device 100 in FIG. 1 comprises a pump system for producing and maintaining a vacuum (not shown in FIG. 1) required in the vacuum chamber 102, With closed control valves 151, 156, 161, 166, 171, 176, a residual gas pressure of ≤10⁻⁷ mbar is achieved in the vacuum chamber 102 of the device 100. The pump system may comprise separate pump systems for the upper part 103 of the device 100 for providing the electron beam 127 and the lower part 107, which includes the sample stage 110 with the sample 105. Furthermore, the device 100 may comprise in the vicinity of the processing point of the electron beam 127 an intake suction device to define a defined local pressure condition on the surface of the sample 105 or the photomask 105 (not shown in FIG. 1). The use of an additional intake suction device can to a large extent prevent one or more volatile reaction products of the one or more precursor gases, which are not needed for the local deposition of the deposition material, from depositing on the photomask 105 and/or in the vacuum chamber 102 or reaction chamber 107. Furthermore, the intake suction device can prevent particles that are formed in an etching process from being distributed in the vacuum chamber 102 of the device 100. The functions of the pump system(s) and of the additional intake suction device can likewise be controlled and/or monitored by the control unit 145 of the computer system 140.

Moreover, the device 100 may have one or more atomic force microscopes (AFM), which allow defects of the sample to be analyzed in detail (not shown in FIG. 1). In addition, it is possible that one or more AFMs are designed to take up the sample processing and the focused electron beam 127 can be used for in situ observation or monitoring of the sample processing. For example, a probe of an AFM may be set up to eliminate a defect of an excess of material by mechanical processing. In addition, a probe of the one or more AFMs may be set up to remove a particle from the sample 105. In addition, a probe may be designed to repair a clear defect by depositing absorbent material.

Finally, the lower part of FIG. 1 schematically shows a cleaning device 190 with a cleaning liquid 195, which is used to clean a sample 105 during and/or after completion of the sample processing in the device 100. The cleaning liquid 195 can be adapted to the sample 105 to be cleaned. The cleaning liquid 195 may comprise water and/or aqueous solutions, such as diluted sulfuric acid or diluted hydrogen peroxide under the action of ultrasound or megasound. Furthermore, the presence of ultraviolet (UV) or infrared (IR) light and also the presence of diluted gases, such as hydrogen (H₂) and/or oxygen (O₂), can enhance the cleaning effect of the cleaning liquid.

In addition, the cleaning device 190 can be used for removing the reference mark(s) present as mark(s) for drift correction from the sample 105. If the marks for drift corrections, a sacrificial layer and/or a protective layer have been deposited with the aid of, for example, the precursor gas Mo(CO)₆, these marks or layers can be removed from the sample 105 with a cleaning liquid 195 which comprises specific solutions such as mineral acids, bases or organic ligands.

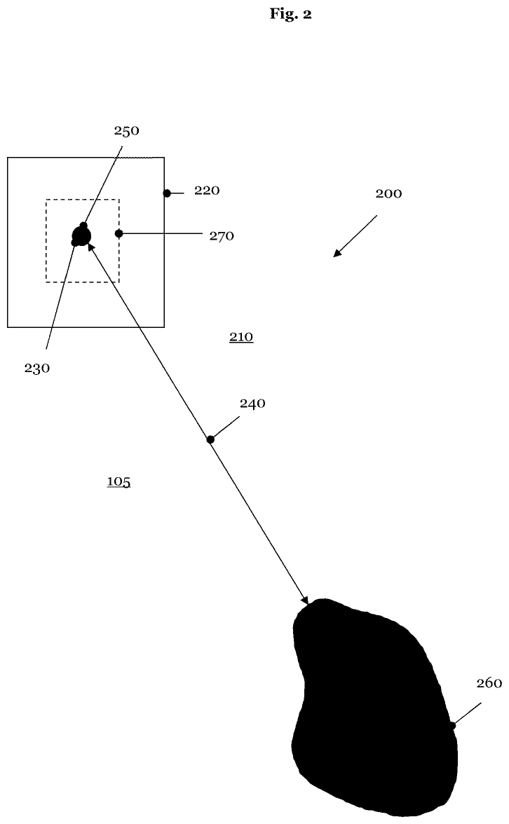

FIG. 2 schematically shows a view of a detail of the photomask as an example of a sample 105. The detail 200 shows a defect 260 on a substrate 210 of the mask, which is intended to be repaired with a particle-beam-induced processing process. The defect 260 can be a defect of missing material, a defect of an excess of material or a particle present on the mask substrate 210. In the example of FIG. 2, a defect 260 is a defect of an excess of material, i.e., a dark defect 260, on the mask substrate 210. In the example shown in FIG. 2, the defect 260 is isolated, i.e., in its vicinity there is no pattern element of the mask which could take up the function of a reference element or on which a reference element could be produced.

In order to compensate for a drift of the particle beam or the electron beam 127 during the sample processing, the detail 200 has a reference element 230 in the form of a mark 230 for drift correction. In the example shown in FIG. 2, the mark 230 has a circular and/or cylindrical shape. To avoid damage during multiple scans of the mark 230 for drift correction for determining the position of the mark 230, the mark 230 or the DC mark 230 (DC meaning drift correction) is deposited on a sacrificial layer 220 of the mask substrate 210. In addition, a defined material contrast of the electron beam 127, as an example particle beam 127, between the sacrificial layer 220 and the reference element 230 can be set by use of the sacrificial layer 220. Moreover, the selection of the material composition of the sacrificial layer 220 can be made such that the latter can be removed from the photomask 105 together with the reference element 230 after completion of the sample processing in a wet chemical cleaning step. In the exemplary embodiment of FIG. 2, the sacrificial layer 220 has a rectangular shape.

The double-headed arrow in FIG. 2 symbolizes the reference distance 240 of the DC mark 230 with respect to the defect 260. The coordinates of the DC mark 230 (based on a coordinate system linked to the sample holder 110) at the start of sample processing define a reference position 250 of the DC mark 230. The coordinates of the two-dimensional vector, which describes the direction and absolute value of a drift between the electron beam 127 and the position of the defect 260, are referred to the reference position 250 of the DC mark 230. The mask detail 200 shown in FIG. 2 has a DC mark 230. It is of course also possible to produce two, three, four and even more reference elements 230 on the mask around the defect 260 and to use them for determining a drift and/or aberrations of the particle beam 127.

The dashed rectangle 270 indicates in FIG. 2 the surface, which the focused electron beam 127 scans to determine the reference position 250 of the reference element 230 before the start of the processing process of the defect 260 of the sample 105. In the example of FIG. 2, the scanning range of the particle beam 127 is located completely on the sacrificial layer 220.

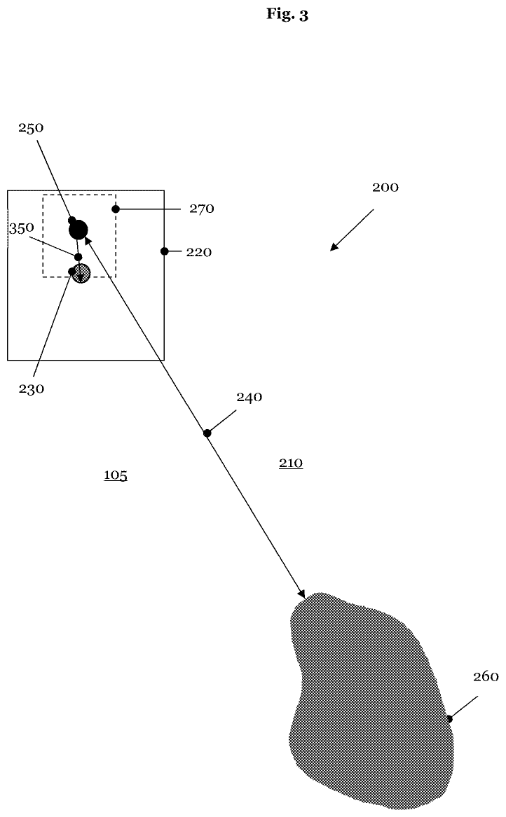

FIG. 3 presents the detail 200 of the photomask after performing a part of or a first part of the sample processing, i.e., the processing process of the defect 260. The dark defect 260 is processed by performing a particle-beam-induced local chemical reaction in the form of an etching process, i.e., removed from the mask substrate 210 by etching. For example, xenon difluoride (XeF₂) can be used as an etching gas. Depending on the material composition of the defect 260, an additive gas, such as an oxidizing agent such as oxygen (O₂) or chlorine (Cl₂) can be added to the etching gas, A combination of two or more etching gases can also be used to remove the defect 260.

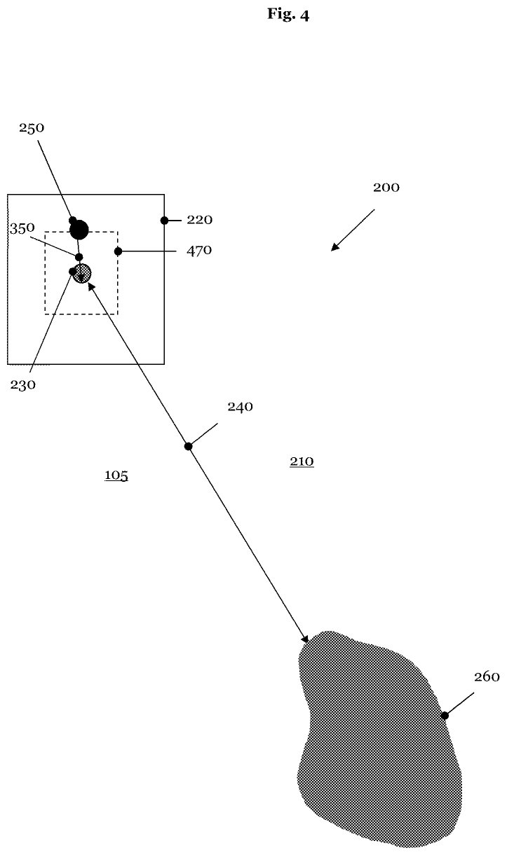

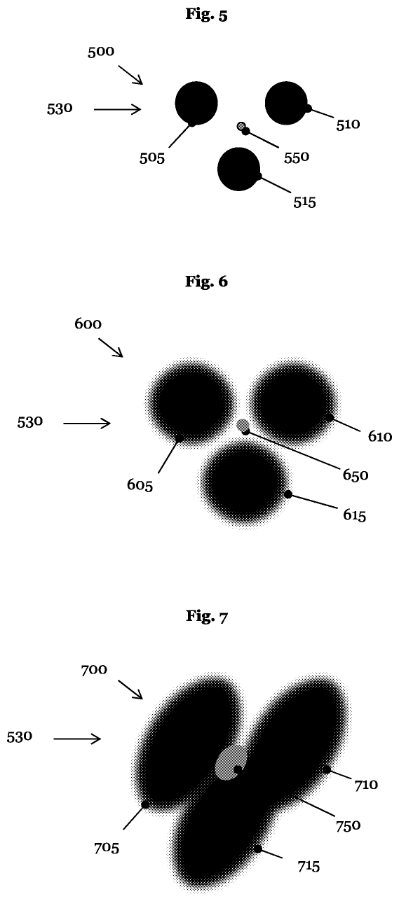

Sample processing in the form of a local chemical reaction is a prolonged process that can last for a time period of a few minutes and can last into the hourly range in the event of large-scale defects. In addition, sample processing may result in a local change in the temperature on the sample 105. Moreover, the use of a precursor gas or a mixture of different precursor gases can change the focus or, more generally, the beam shape of the focused electron beam 127. These effects of sample processing can cause a drift of the electron beam 127 relative to the defect 260 to be processed. The correction of a drift is explained using FIGS. 3 and 4. In addition, the described effects can change the beam shape or beam geometry of the focused particle beam 127. The consequences of a beam change and the elimination thereof are discussed below on the basis of FIGS. 5 to 7.

Sample processing is interrupted due to the influence of the above effects, and the focused electron beam 127 is displaced by the reference distance 240 in order to scan the DC mark 230 again without the provision of a precursor gas. If the approach of the position of the reference mark, the scanning of which is carried out with the focused electron beam 127, and the determination of the imaging error of the focused electron beam 127 take place within a short period of time, the interruption of the provision of the precursor gas can be dispensed with. This avoids the need to wait for the amount of time after the gas flow has been interrupted until the latter has stabilized after being switched on.

As illustrated in FIG. 3 by the vector 350, the DC mark 230 has shifted within the scanning range 270. This means that the processing window of the focused electron beam 127 has shifted relative to the defect 260 to be etched. In order to examine in detail the drift 350 of the DC mark 230 with respect to its reference position 250, the scanning range 270 of the electron beam 127 in the present example is displaced substantially around the drift vector 350 and the DC mark 230 is scanned again. Starting from the new position of the DC mark 230, the focused electron beam 127 is displaced again by the reference distance 240 and the processing of the defect 260 is continued.

This process is illustrated in FIG. 4. In FIGS. 3 and 4, the defect 260 is reproduced in a greyscale, whereas the defect 260 in FIG. 2 is shown in black. This is to symbolize that the defect 260 in FIGS. 3 and 4 has already been partially removed by etching, i.e., FIGS. 3 and 4 show a residual defect of the original defect 260. Sample processing may be interrupted a second time, generally n times, if required, to detect drift and/or aberrations of the focused electron beam at the end of the n-th processing interval or at the end of the n-th loop.

FIG. 5 presents an image 500 of a reference element 530 which was recorded with a best possible parameter setting of the electron beam 127, with the result that the image contains a minimum of aberrations. The image 500 thus represents a reference image 500 of the reference element 530. The reference element 530 has three cylindrical structures 505, 510, 515 arranged at the ends of an isosceles or equilateral triangle. The center of gravity of the reference element 530 can be selected as the reference position 550 of the reference element 530.

Like the reference element 230, the reference element 530 is not a pattern element that is present on the sample 105 or photomask. Rather, the reference element 530 is a mark for drift correction. The reference element 530 may, for example, comprise the reference element 230 of FIG. 2. This means that the reference element 530 can be deposited on a sacrificial layer 210 of the sample by use of an electron-beam-induced deposition process with the aid of a deposition gas or a deposition gas mixture. However, it is also possible to etch the reference element 530 or the mark 530 for drift correction into the sacrificial layer 210. In addition, the DC mark 530 can be deposited directly on the mask substrate 210 of the mask 105 or be etched into the mask substrate 210 thereof.

As already described in the context of FIG. 2, the reference image 500 of the reference element 530 or the DC mark 530 can be used to determine the reference position 550 of the DC mark 530. The reference position 550 of the DC mark 530 can be determined with great precision on the basis of the reference image 500.

As already explained in the context of FIG. 3, after a part of the processing of the defect 260, the sample processing is interrupted and the DC mark 230 is−with or without interruption of the precursor gas flow—scanned again with the focused electron beam 127 in order to obtain an image of the DC mark 230. FIG. 6 presents an image 600 of the DC mark 530 of FIG. 5 after an interruption of the sample processing. In the image 600 of FIG. 6, the DC mark 530 has in comparison to the reference image 500 an increased amount of aberrations due to a defocusing of the electron beam 127. The increased amount of aberrations represented by the enlarged blurred structures 605, 610, 615 of the cylindrical structures 505, 510, 515 of the reference element 530 reduces the accuracy with which the position 650 of the drift mark 530 can be determined. This reduces the precision of the determination of the drift vector 350. In addition, the defocused electron beam 127 increases the lateral dimensions of a local etching reaction for removing the defect 260, thereby reducing the lateral resolution of the sample processing.

By determining the extent of the misfocusing and correcting it, a reference image 500 of the DC mark 530 can be recorded again after the sample processing was interrupted. The extent of the drift, illustrated by the two-dimensional vector 350, can be corrected in an optimal manner, as described in the context of FIGS. 3 and 4, in which the changes in the beam shape of the focused electron beam 127 were ignored. Furthermore, the beam geometry can be optimized to perform the local etching reaction for removing the defect 260, to perform the second part of sample processing. A deterioration of the process resolution of a local chemical reaction, a local electron-beam-induced etching reaction in the example of FIGS. 2 to 4, during sample processing can thus be prevented. The determination and correction of aberrations that occur as defocusing of the focused electron beam 127 have been explained in the context of the explanation of the device 100. In addition, it has been stated there how the device 100 can correct defocusing of the electron beam 127.

FIG. 7 presents a second type of aberration, which can deteriorate the image quality of the focused electron beam 127 during sample processing. When the image 700 of the reference mark 530 was recorded, the focused particle beam 127 exhibited astigmatism. The astigmatism of the focused electron beam 127 images the elements 505, 510, 515 of the DC mark 530 as blurred enlarged ellipses 705, 710, 715. Determining the position 750 of the DC mark 730 is subject to greater uncertainty. As already explained in the context of FIG. 6, the drift vector 350 can be determined only imprecisely and the beam shape of the focused particle beam 127 is only conditionally suitable for carrying out a local etching reaction for removing the defect 260 of an excess of material.

The stigmator of the device 100 generates an electric or a magnetic quadrupole field which can be used to correct the astigmatism of the focused electron beam 127. The focused electron beam 127, which records an image of the DC mark 530 with modified parameter settings of the stigmator that correct its astigmatism, generates a reference image 500 of the mark 530 for drift correction. After determining the extent of the astigmatism and its correction by use of the stigmator of the device 100, the extent of a drift 350 can be corrected in an optimal manner and the sample processing can be continued with an optimized beam geometry of the focused particle beam 127.

A coma, not shown here, is another type of aberration by which an imaging error of a focused particle beam 127 can be enlarged during sample processing. This type of aberration is typically caused by an oblique passage of the particle beam 127 through the objective lens 125 of the device 100. This type of aberration also reduces the accuracy with which the position of a DC mark 530 can be determined. By guiding the particle beam 127 through the optical center of the objective lens 125 of the device 100, a coma of the focused particle beam 127 can be largely avoided and the beam shape of the focused electron beam 127 can be optimized for a further part of the sample processing.

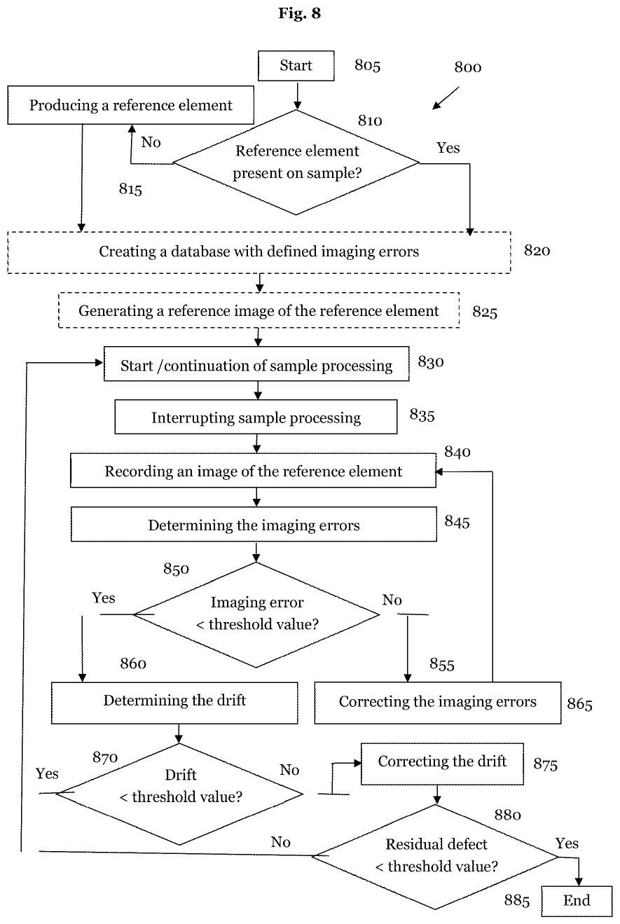

FIG. 8 schematically presents a flowchart 800 of a method according to the invention in order to correct both aberrations of a focused particle beam 127 and a drift of the particle beam 127 relative to a defect 260 to be processed during sample processing. The method begins in step 805. First, at decision block 810, a check is performed as to whether one or more structure elements are present on the sample 105 to be processed which are suitable for use as reference element 230, 530. If this is not the case, step 815 produces one or more reference elements 230, 530 near the defect 260 to be processed. Typically, one or more reference elements 230, 530 in the form of one or more marks 230, 530 for drift correction are produced by use of a particle-beam-induced etching process and/or deposition process on the sample 105.

In a possible embodiment of a method according to the invention, in step 820, a database with images of the at least one reference element 230, 530 is created, in which the focused particle beam 127 has a defined imaging error, by imaging the one or more reference elements 230, 530 with a defined misaligned focused particle beam 127. Since the performance of step 820 is necessary only in a specific embodiment, it is shown by dashes in FIG. 8.

In step 825, a reference image 500 of the at least one reference element 530 is generated by scanning the focused particle beam 127 over the reference element 530. This step is also not necessary for all variants of a method according to the invention and is therefore also characterized as being optional by dashes. For example, a reference image 500 of the at least one reference element 530 can be stored in a database.

In step 830, the actual sample processing starts by the combination of a focused particle beam 127 and at least one etching gas etching the defect 260 of FIGS. 2 to 4.

After a fixed or variable time interval, sample processing or defect processing is interrupted in step 835. If necessary, the gas flow of the etching gas can be stopped. If required, one or more parameters of the focused particle beam 127 for scanning the reference element 230, 530 are also changed.

In step 840, the focused particle beam 127 records an image 600, 700 of the reference element 230, 530 by scanning over the reference element 530. In the next step 845, the reference image 500 of the reference element 530 is compared with the image 600, 700 of the reference element 530 at the end of the first part of the sample processing. From this comparison, the imaging error(s) of the focused particle beam 127 are determined at the end of the first loop of the defect repair process. Further possible exemplary embodiments of the determination of the aberrations have already been described above, for example, the use of a database with defined imaging errors, the use of an auto-correction function and/or the use of a trained model of machine learning.

In decision block 850, it is then determined whether the specific imaging error falls below or exceeds a specified threshold value. If the determined imaging error exceeds the threshold value, the imaging error is corrected and the method jumps back to block 840, where an image 500 of the reference element 530 is recorded again. Possibilities for correcting various aberrations are explained in the context of the discussion of FIG. 1.

If the imaging error(s) of the focused particle beam 127 is/are less than the specified threshold value, the two-dimensional vector 350, which describes the drift of the focused particle beam 127 relative to the defect 260 to be processed during the first processing interval, is determined in step 860. If the drift is likewise smaller than the associated threshold value, the method at decision block 875 jumps back to block 830 and the second part of the sample processing continues with the original parameter values of the focused particle beam 127. If, on the other hand, it is determined at decision block 875 that the absolute value of the drift vector 350 is greater than the threshold value of the drift correction, the drift of the particle beam 127 with respect to the reference position 550 of the reference element 530 is corrected in step 875.

In addition, it is decided at decision block 880 whether the defect 250 remaining after the first loop or its residual defect exceeds a permissible threshold value. If this is the case, the method jumps back to block 830 and a second defect processing loop is performed. If, on the other hand, it is determined at decision block 880 that the residual defect no longer interferes with the function of the sample 105 in an unacceptable manner, the method ends with step 885.

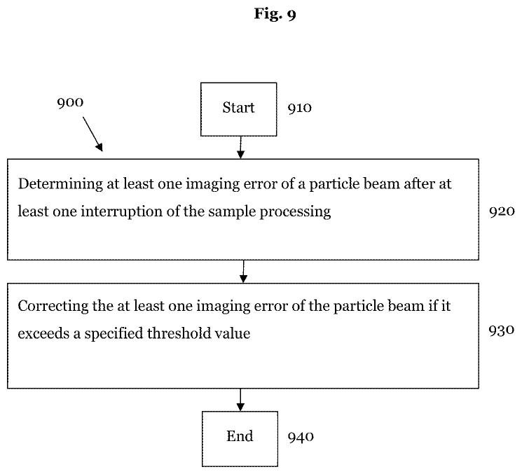

Finally, the flowchart 900 of FIG. 9 represents essential steps of a method for correcting an imaging error of a particle beam 127 during sample processing. The method begins in step 910. In step 920, at least one imaging error of the particle beam 127 is determined after at least one interruption of the sample processing. This can be done, for example, by comparing a reference image 500 of a reference element 520 with an image 600, 700 of the reference element 530, which is recorded after sample processing was interrupted. Furthermore, the determination of the image error(s) can be carried out on the basis of a database with defined imaging errors and/or by the use of an auto-correction function. The use of a trained model of machine learning is also possible. The method ends in step 940.

What is claimed is:

1. A method for correcting at least one imaging error of a particle beam during processing of a sample, comprising the steps of:
a. determining the at least one imaging error of the particle beam after at least one interruption of the processing of the sample, wherein processing of the sample comprises a controlled modification of the sample; and
b. correcting the determined at least one imaging error of the particle beam if it exceeds a specified threshold value.

2. The method according to claim 1, wherein the processing of the sample comprises using the particle beam for processing the sample.

3. The method according to claim 1, wherein the processing of the sample comprises providing at least one precursor gas on the sample.

4. The method according to claim 1, wherein an interruption of the processing of the sample comprises at least the interruption of the provision of the at least one precursor gas.

5. The method according to claim 1, wherein the determination of the at least one imaging error of the particle beam comprises: recording at least one image of at least one reference element of the sample with the particle beam.

6. The Method according to claim 5, wherein the at least one reference element comprises at least one element from the group of: at least one structure element of the sample, at least one mark for drift correction or at least one defect of the sample.

7. The method according to claim 1, furthermore comprising the following step: depositing a sacrificial layer on the sample and/or a protective layer around a processing site of the sample with a particle beam and at least one precursor gas in the form of a deposition gas.

8. The method according to claim 6, wherein determining the at least one imaging error comprises: analyzing the at least one recorded image with respect to at least one reference.

9. The method according to claim 8, wherein the at least one reference comprises at least one element from the group of: at least one reference image of the at least one reference element, stored data which were determined from the at least one reference image of the at least one reference element, at least one reference image recorded by the particle beam, stored data which were determined from the reference image recorded by the particle beam, a database with at least two images of the at least one reference element recorded with a particle beam having at least one defined imaging error, or a database of stored data which have been determined from the at least two images of the at least one reference element recorded with a particle beam having at least one defined imaging error.

10. The method according to claim 9, further comprising: systematic change of at least one parameter of the particle beam before recording at least one of the at least two images of the at least one reference element for producing the at least one defined imaging error.

11. The method according to claim 1, wherein the correction of the determined at least one imaging error comprises the use of at least one element from the group of: an auto-correction function or a trained model of machine learning.

12. The method according to claim 1, wherein the correction of the determined imaging error comprises a change of at least one parameter of the particle beam, so that the particle beam with the at least one changed parameter substantially generates a reference image when recording an image of the at least one reference element.

13. The method according to claim 1, wherein the at least one imaging error comprises at least one element from the group of: a change in focus, a change in astigmatism or a change in coma.

14. The method according to claim 3, wherein the at least one precursor gas comprises at least one element from the group of: at least one etching gas, at least one deposition gas or at least one additive gas.

15. The method according to claim 5, wherein the at least one reference element comprises at least one mark for drift correction, and the method further comprises the step of: removing the at least one mark for drift correction from the sample.

16. A computer program comprising instructions that cause a computer system to carry out the method steps of claim 1 when the computer program is executed by the computer system.

17. A device for correcting at least one imaging error of a particle beam during processing of a sample, comprising:
a. means for determining at least one imaging error of the particle beam after at least one interruption of the processing of the sample, wherein processing of the sample comprises a controlled modification of the sample; and
b. means for correcting the determined at least one imaging error of the particle beam if it exceeds a specified threshold value.

18. The device according to claim 17, further comprising at least one element from the group of: means for providing at least one precursor gas on the sample, means for guiding and controlling a gas flow rate of at least one precursor gas, means for producing, focusing and scanning the particle beam, means for adjusting a focus, an astigmatism and a coma of the particle beam, means for adjusting an objective lens, which is used for focusing the particle beam, means for displacing the sample in the beam direction of the particle beam, means for adjusting a stigmator, or means for positioning the particle beam relative to a multi-aperture stop and/or for positioning the multi-aperture stop relative to the particle beam.

19. The device according to claim 17, further comprising: a stigmator for changing an astigmatism of the particle beam.

20. The device according to claim 17, further comprising: a multi-aperture stop for producing a specified particle stream.

21. The device according to claim 17, further comprising: a computer system with a computer program comprising instructions that, when executed by the computer system, cause the computer system to carry out a method for correcting the at least one imaging error of the particle beam during processing of the sample, the method comprising:
determining the at least one imaging error of the particle beam after the at least one interruption of the processing of the sample, wherein the processing of the sample comprises the controlled modification of the sample; and
correcting the determined at least one imaging error of the particle beam if it exceeds the specified threshold value.
